(19) United States
(12) Patent Application Publication
(10) Pub. No.: US 2023/0090280 A1
(43) Pub. Date: Mar. 23, 2023

(54) SELECTIVE GRAPHENE DEPOSITION

(71) Applicant: Applied Materials, Inc., Santa Clara, CA (US)

(72) Inventors: Supriya Ghosh, San Jose, CA (US); Susmit Singha Roy, Sunnyvale, CA (US); Abhijit Basu Mallick, Fremont, CA (US)

(73) Assignee: Applied Materials, Inc., Santa Clara, CA (US)

(21) Appl. No.: 17/483,273

(22) Filed: Sep. 23, 2021

(51) Int. Cl. H01L 21/768; H01L 21/02; H01L 21/311

(52) U.S. Cl. CPC H01L 21/76834; H01L 21/02115; H01L 21/31122

(57) ABSTRACT

Exemplary semiconductor processing methods may include providing a carbon-containing precursor to a processing region of a semiconductor processing chamber. A substrate may be disposed within the processing region of the semiconductor processing chamber. The substrate may include a low dielectric constant material defining one or more features, a liner extending across the low dielectric constant material and within the one or more features, and a metal-containing layer deposited on the liner and extending within the one or more features. The methods may include forming a layer of material on at least a portion of the liner and the metal-containing layer. The layer of material may include graphene. The methods may include removing substantially all of the portion of the layer of material on the liner.

### TECHNICAL FIELD

The present technology relates to semiconductor processes and materials. More specifically, the present technology relates to selectively depositing graphene on metal.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Desirable characteristics in films may vary depending on their application.

Thus, there is a need for improved systems and methods that can be used to produce high quality devices and structures. These and other needs are addressed by the present technology.

### SUMMARY

Exemplary methods of forming semiconductor structures may include providing a carbon-containing precursor to a processing region of a semiconductor processing chamber. A substrate may be disposed within the processing region of the semiconductor processing chamber. The substrate may include a low dielectric constant material defining one or more features, a liner extending across the low dielectric constant material and within the one or more features, and a metal-containing layer deposited on the liner and extending within the one or more features. The methods may include forming a layer of material on at least a portion of the liner and the metal-containing layer. The layer of material may be or include graphene. The methods may include removing substantially all of the portion of the layer of material on the liner.

In some embodiments, the carbon-containing precursor may include a carbon-carbon double bond or a carbon-carbon triple bond. A flow rate of the carbon-containing precursor to the processing region of the semiconductor processing chamber may be less than or about 1,500 sccm. A temperature within the semiconductor processing chamber may be maintained at less than or about 540° C. while forming the layer of material. A pressure within the semiconductor processing chamber may be maintained at less than or about 50 Torr while forming the layer of material. In some embodiments, a temperature within the semiconductor processing chamber may be maintained at less than or about 450° C. while forming the layer of material and a pressure within the semiconductor processing chamber may be maintained at less than or about 25 Torr while forming the layer of material on the substrate. The layer of material may be characterized by a carbon concentration of greater than or about 80 at. %. The layer of material formed on the metal-containing layer may be characterized by a thickness of less than or about 15 nm. The methods may include providing a hydrogen-containing precursor to the processing region of the semiconductor region prior to removing substantially all of the portion of the material on the liner. The methods may include forming a plasma of the hydrogen-containing precursor. The plasma may be formed at a plasma power of less than or about 100 W.

Some embodiments of the present technology may encompass semiconductor processing methods. The methods may include providing a precursor to a processing region of a semiconductor processing chamber. The precursor may be or include acetylene. A substrate may be disposed within the processing region of the semiconductor processing chamber. The substrate may include a low dielectric constant material defining one or more features and a metal-containing layer deposited on the low dielectric constant material and extending within the one or more features. The methods may include forming a layer of material on at least a portion of the low dielectric constant material and the metal-containing layer. The layer of material may be or include graphene. The methods may include providing a hydrogen-containing precursor to the processing region of the semiconductor region, forming a plasma of the hydrogen-containing precursor, and contacting the layer of material with the plasma effluents and removing substantially all of the layer of material on the low dielectric constant material.

In some embodiments, a flow rate of the carbon-containing precursor to the processing region of the semiconductor processing chamber may be less than or about 1,250 sccm. A temperature within the semiconductor processing chamber may be maintained at less than or about 500° C. while forming the layer of material. A pressure within the semiconductor processing chamber may be maintained at less than or about 30 Torr while forming the layer of material on the substrate. The layer of material may be formed in less than or about 900 seconds. The plasma may be formed at a plasma power of less than or about 50 W.

Some embodiments of the present technology may encompass semiconductor processing methods. The methods may include providing a carbon-containing precursor to a processing region of a semiconductor processing chamber. A substrate may be disposed within the processing region of the semiconductor processing chamber. The methods may include forming a layer of material on at least a portion of the substrate. The layer of material may include graphene. The methods may include removing substantially all of the layer of material that is amorphous.

In some embodiments, the substrate may include a liner defining one or more features and a metal-containing layer deposited on the liner and extending within the one or more features. Substantially all of the layer of material on the liner may be amorphous. The carbon-containing precursor may be or include acetylene. The layer of material may be formed in less than or about 600 seconds. Removing substantially all of the layer of material that is amorphous may include contacting the layer of material with effluents of a hydrogen-containing plasma.

Such technology may provide numerous benefits over conventional systems and techniques. For example, the processes and structures may selectively deposit a layer of material that serves as both a conductive layer and a barrier layer. Additionally, the operations of embodiments of the present technology may reduce the thickness of the overall structure as a conductive layer and a barrier layer are combined into one layer of material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary semiconductor processing chamber according to some embodiments of the present technology.

FIG. 2 shows selected operations in a formation method according to some embodiments of the present technology.

FIGS. 3A-3C show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During metallization formation in semiconductor processing, diffusion barriers may be included about structures defining conductive lines. Copper and cobalt, among other metals or conductive materials, may operate efficiently as interconnects, even as device and feature structures are shrinking. The materials may be characterized by lower electrical resistivity and improved electromigration resistance. However, these materials may be susceptible to atomic diffusion, where the metallic species can diffuse through dielectric materials causing short-circuiting between separated lines, and which may lead to device failure. Accordingly, diffusion barriers may be included about the metallic materials to limit diffusion. Diffusion barrier materials may include a host of materials including metal nitrides, such as titanium nitride and tantalum nitride. These materials may be deposited about sidewalls and bases of features defined in dielectric materials, and which may fully contain metal deposited in the feature and limit or prevent diffusion. Additionally, one of these materials, or a metal capping layer, may be formed overlying the metal once the features have been filled. For example, by utilizing a metal capping layer, atomic diffusion may be prevented, while also providing additional conductive material to limit resistivity increases for smaller feature sizes.

However, these materials may cause a number of issues, which may be exacerbated with shrinking feature sizes. For example, metal capping layers may cause challenges in ensuring feature separation, and if not fully removed between features, may cause shorting between conductive lines. Additionally, materials like titanium or tantalum nitride may become discontinuous at shrinking thicknesses, which may allow atomic migration or diffusion to occur. Because of these and other issues, conventional technologies have been limited in the ability to further reduce feature sizes or prevent shorting between features due to diffusion or incomplete material removal.

The present technology overcomes these issues by utilizing graphene that is selectively deposited on metal materials. The two-dimensional structure of graphene may allow reduced thickness layers that still effectively operate as diffusion barriers. Graphene is also a conductive material, which can help to limit resistivity gains as interconnects continue to shrink. Additionally, by performing operations according to some embodiments of the present technology, the graphene can be selectively deposited on the metal lines, and may not be deposited or have limited deposition on intervening barrier or dielectric materials, which can limit or prevent conductive material extending between adjacent features that can lead to shorting. Finally, any residual graphene that may be formed between features according to the present technology may be easily removed with minimal to no damage to the graphene barrier materials.

Although the remaining disclosure will routinely identify specific deposition processes utilizing the disclosed technology, and will describe one type of semiconductor processing chamber, it will be readily understood that the processes described are equally applicable to other deposition chambers, as well as processes that may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

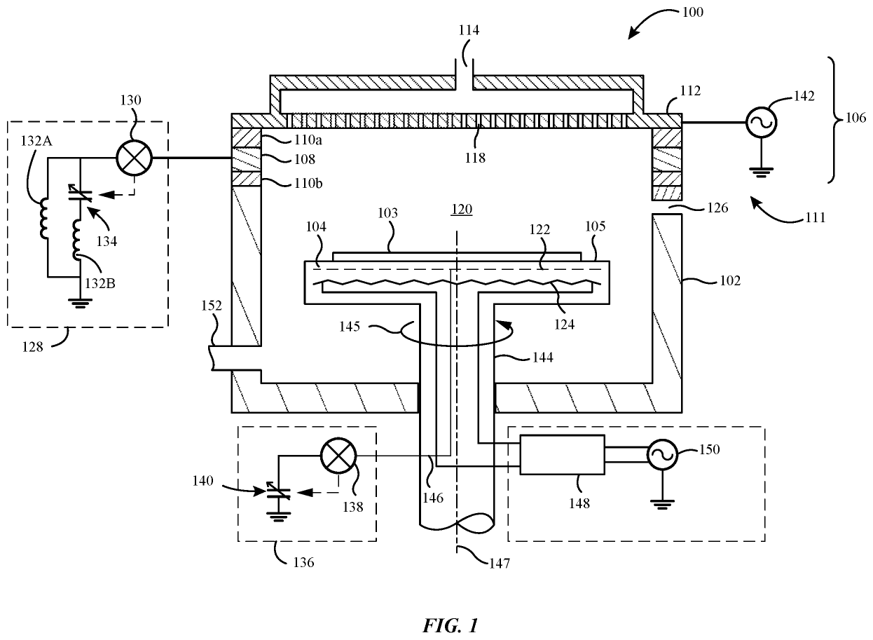

FIG. 1 shows a cross-sectional view of an exemplary semiconductor processing chamber system 100 according to some embodiments of the present technology. Semiconductor processing chamber 100 may be utilized to form film layers according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a faceplate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

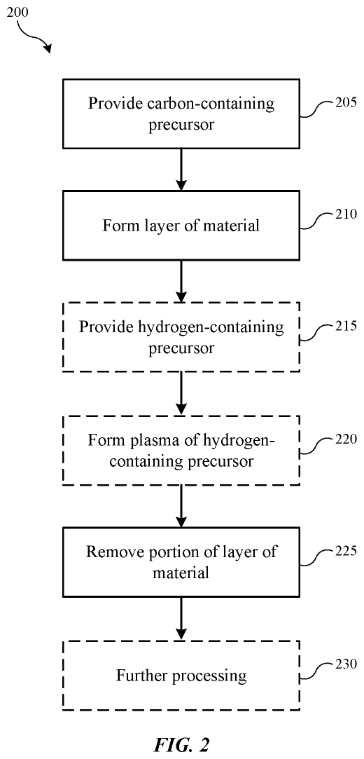

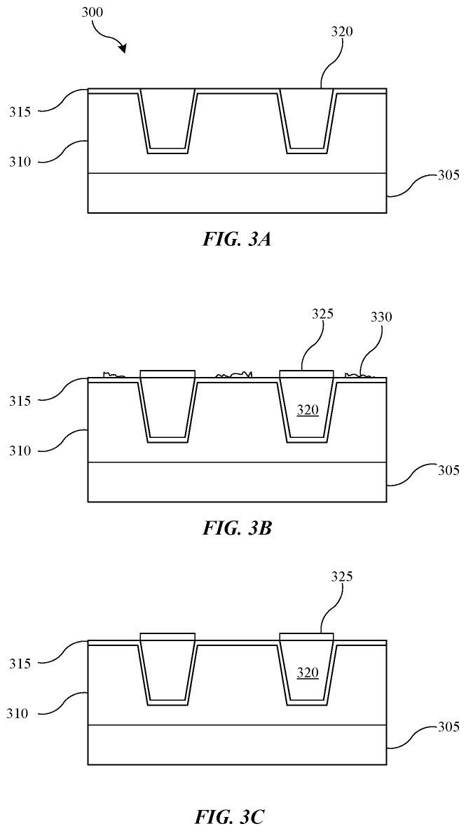

Although a plasma-processing chamber may be used for one or more aspects of film processing according to the present technology, in some embodiments, forming carbon films may not utilize a plasma-enhanced process. Utilizing plasma may limit conformality of the film produced by further releasing carbon from precursors, and which may limit carbon incorporation in the films produced by allowing the carbon to recombine with other radical species and flow from the chamber. The present technology may at least form the film without plasma generation in some embodiments. FIG. 2 shows operations of an exemplary method 200 of semiconductor processing according to some embodiments of the present technology. The method may be performed in a variety of processing chambers, including the semiconductor processing chamber 100 described above, as well as any other chamber in which plasma deposition may be performed. Method 200 may include a number of optional operations, which may or may not be specifically associated with some embodiments of methods according to the present technology. It is to be understood that method 200 may be performed on any number of semiconductor structures or substrates, including exemplary structure 300 or substrate 305 as illustrated in FIGS. 3A-3C on which layers of material may be formed. It is to be understood that FIGS. 3A-3C illustrate only partial schematic views, and a substrate may contain any number of structural sections having aspects as illustrated in the figures, as well as alternative structural aspects that may still benefit from operations of the present technology.

Method 200 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. As previously discussed, method 200 may describe operations shown schematically in FIGS. 3A-3C, the illustrations of which will be described in conjunction with the operations of method 200.

Prior to the first operation of the method 200, the substrate 305 may be processed in one or more ways before being placed within a processing region of a semiconductor processing chamber 100 in which method 200 may be performed. Some or all of the operations may be performed in chambers or system tools as previously described, or may be performed in different chambers on the same system tool, which may include the semiconductor processing chamber in which the operations of method 200 may be performed.

The methods may include providing a carbon-containing precursor to a processing region of a semiconductor processing chamber 100 at operation 205. Substrate 305 may be disposed within the processing region of the semiconductor processing chamber 100. Substrate 305 may have a substantially planar surface or an uneven surface in embodiments. The substrate may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 305 may have various dimensions, such as 200 mm or 300 mm diameter wafers, as well as rectangular or square panels.

A low dielectric constant material 310 may be formed overlying the substrate. The low dielectric constant material 310 may define one or more features, which may define interconnect or metallization line locations. The low dielectric constant material 310 may include, but is not limited to oxide materials, such as silicon oxide, or doped oxides with fluorine, carbon, or other low-k materials that may be used in processing. A liner 315 may extend across the low dielectric constant material 310 and within the one or more features. The liner 315 may include, but is not limited to, tantalum nitride or titanium nitride, although any other barrier materials may be used in embodiments of the present technology. A metal-containing material 320 may be deposited on the liner 315 and may extend within the one or more features, which may produce interconnect or metallization lines across a layer of the substrate. The metal-containing material 320 may be any number of metals such as copper, cobalt, tungsten, or other metal materials.

As previously discussed, at operation 205, the method 200 may include providing the carbon-containing precursor to a processing region of a semiconductor processing chamber 100. Carbon-containing precursors that may be used in deposition may be or include any number of carbon-containing precursors. For example, the carbon-containing precursor may be or include any hydrocarbon, or any material including or consisting of carbon and hydrogen. In some embodiments, the carbon-containing precursor may be characterized by one or more carbon-carbon double bonds and/or one or more carbon-carbon triple bonds. Accordingly, in some embodiments the carbon-containing precursor may be or include an alkane, alkene, or an alkyne, such as acetylene, ethylene, propene, or any other carbon-containing material. The precursor may include carbon-and-hydrogen-containing precursors, which may include any amount of carbon and hydrogen bonding, along with any other element bonding. While various carbon-containing precursors, such as ethylene and ethane, are contemplated, acetylene may demonstrate improved deposition characteristics. The metal on which the deposition may be sought may catalyze acetylene at a lower temperate than ethylene and ethane. As will be appreciated by one skilled in the art, lower temperatures may be preferable due to thermal budgets during processing.

As previously discussed, some or all of the formation operations may be performed while the substrate processing region is maintained plasma-free. By performing a thermal chemical-vapor deposition, a more conformal material formation may be produced, as well as a material characterized by increased carbon incorporation. A flow rate of the carbon-containing precursor to the processing region of the semiconductor processing chamber 100 may be less than or about 1,500 sccm, and may be less than or about 1,400 sccm, less than or about 1,300 sccm, less than or about 1,250 sccm, less than or about 1,200 sccm, less than or about 1,100 sccm, less than or about 1,000 sccm, less than or about 900 sccm, less than or about 800 sccm, less than or about 700 sccm, less than or about 600 sccm, less than or about 500 sccm, or lower. During operation 205, a portion of the carbon-containing precursor may react with the metal-containing layer 320. For example, a portion of the carbon-containing precursor may react with the metal in the metal-containing layer 320, such as cobalt or copper, and the metal will consume carbon and form alloys of the metal and carbon, which may detrimentally reduce efficiency of the line metals. At lower flow rates, such as less than or about 1,500 sccm, the amount of carbon consumption by the metal-containing layer 320 may be reduced while still maintaining the formation of the graphene layer of material on the metal-containing layer 320.

In addition to the carbon-containing precursor, a hydrogen-containing precursor may also be provided to the processing region of a semiconductor processing chamber 100. A flow rate of the hydrogen-containing precursor to the processing region of the semiconductor processing chamber 100 may be greater than or about 700 sccm, and may be greater than or about 800 sccm, greater than or about 900 sccm, greater than or about 1,000 sccm. In embodiments, the hydrogen-containing precursor may be or include diatomic hydrogen.

At operation 210, the method 200 may include a selective deposition operation that includes forming a layer of material, including a portion of the layer of material 325 on the metal-containing layer 320, while limiting or preventing formation on intervening portions of the structure, such as on the liner material 315. In embodiments, the portion of the layer of material 325 on the metal-containing layer 320 may include graphenic carbon, whereas a portion of the layer of material 330 on the liner may include amorphous carbon. The metal in the metal-containing layer 320 may catalyze decomposition of the carbon-containing materials at lower processing temperatures utilized in embodiments of the present technology. This may allow growth to occur over the metal materials, while limiting or preventing growth over dielectric or barrier materials. Additionally, the metal may catalyze graphene formation, which may form a high-quality graphene layer overlying the metal. While some amount of carbon material may form on the barrier material between metal features, this material may be limited to amorphous carbon, which may be easily removed as discussed further below.

The portion of the layer of material 325 on the metal-containing layer 320 may be characterized by a carbon concentration of greater than or about 80 at. %, and may be characterized by a carbon concentration of greater than or about 82 at. %, greater than or about 84 at. %, greater than or about 86 at. %, greater than or about 88 at. %, greater than or about 90 at. %, or higher. Carbon concentrations greater than or about 80 at. % may improve conductivity, and contribute to the portion of the layer of material 325 serving as both a conductive layer and a barrier layer. Higher carbon concentrations may result in the portion of the layer of material 325 being characterized by a more complete graphene lattice, which may contribute to serving as a barrier layer and preventing atomic diffusion across the layer of material 325. The portion of the layer of material 325 formed on the metal-containing layer 320 may be characterized by a thickness of less than or about 15 nm, and may be characterized by a thickness of less than or about 14 nm, less than or about 13 nm, less than or about 12 nm, less than or about 11 nm, less than or about 10 nm, less than or about 9 nm, less than or about 8 nm, less than or about 7 nm, less than or about 6 nm, less than or about 5 nm, less than or about 4 nm, less than or about 3 nm, or lower. By utilizing graphene as an atomic diffusion barrier, a reduced thickness may be afforded, which still ensure complete protection from metal diffusion. Additionally, the graphene may advantageously reduce line resistance within the structure. As previously discussed, as device sizes continue to shrink, the thickness of layers within the devices may need to shrink as well, and graphene may permit this shrinking while controlling resistance increases.

At operation 210, the portion of the layer of material 325 may be formed in less than or about 900 seconds. For example, portion of the layer of material 325 may be formed in less than or about 800 seconds, less than or about 700 seconds, less than or about 600 seconds, less than or about 500 seconds, less than or about 400 seconds, less than or about 300 seconds, or lower. Similar to the effects associated with the flow rate of the carbon-containing precursor, forming the portion of the layer of material 325 over a longer time period may increase the undesirable interaction of the carbon-containing precursor and the metal in the metal-containing layer 320, and may also increase formation along intervening materials. At times of greater than 900 seconds, the saturation of the carbon-containing precursor in the semiconductor processing chamber may result in the metal and the carbon-containing precursor reacting and forming alloys.

As previously discussed, the layer of material may be characterized by the portion of material 325 formed on the metal-containing layer 320 and the portion of material 330 formed on the liner 315. Due to the interaction with the underlying layers, the carbon-containing precursor may deposit differently on each of the metal-containing layer 320 and the liner 315. For example, the portion of the layer of material 325 formed on the metal-containing layer 320 may be crystalline or formed. Conversely, the portion of the layer of material 330 formed on the liner 315 may be amorphous or non-crystalline, which may facilitate removal as discussed further below.

A temperature within the semiconductor processing chamber 100 may be maintained at less than or about 540° C. while forming the layer of material. At temperatures higher than 540° C., metal consumption in the metal-containing layer 320 may increase as the metal incorporates carbon and forms alloys. Accordingly, temperature within the semiconductor processing chamber 100 may be maintained at less than or about 530° C. while forming the layer of material, such as less than or about 520° C., less than or about 510° C., less than or about 500° C., less than or about 490° C., less than or about 480° C., less than or about 470° C., less than or about 460° C., less than or about 450° C., less than or about 440° C., less than or about 430° C., less than or about 420° C., less than or about 410° C., less than or about 400° C., or lower. As the formation of the layer of material may be a thermally-based reaction temperatures lower than about 300° C. may challenge layer formation of material 325, and thus the temperature may be maintained at greater than or about 300° C., greater than or about 350° C., greater than or about 400° C., or more.

A pressure within the semiconductor processing chamber 100 may be maintained at less than or about 50 Torr while forming the layer of material. Pressures higher than 50 Torr may increase metal consumption when contacted with the carbon-containing precursor. Further, higher pressures may reduce the deposition rate of the layer of material. Accordingly, pressure within the semiconductor processing chamber 100 may be maintained at less than or about 45 Torr while forming the layer of material, such as less than or about 40 Torr, less than or about 35 Torr, less than or about 30 Torr, less than or about 25 Torr, less than or about 20 Torr, less than or about 15 Torr, or lower.

After the portion of the layer of material 325 is formed to a sufficient thickness on the metal-containing layer 320, operation 225 may include removing any residual carbon-containing material that may have deposited on the liner 315. While an oxygen-containing removal may be used in some embodiments of the present technology, an oxygen plasma process may cause pitting or removal of the graphene material on the metal regions, which is intended to remain. Accordingly, in some embodiments of the present technology, the method 200 may include providing a hydrogen-containing precursor to the processing region at operation 215 to perform a more controlled removal of carbon-containing material on the liner 315, which may allow the graphene material to be substantially, essentially, or fully retained on the metal materials. The method 200 may also include forming a hydrogen-containing plasma of the hydrogen-containing precursor at operation 220. The plasma may be formed at a plasma power of less than or about 100 W. The plasma may be formed at a plasma power of less than or about 90 W, less than or about 80 W, less than or about 70 W, less than or about 60 W, less than or about 50 W, less than or about 45 W, less than or about 40 W, less than or about 35 W, less than or about 30 W, less than or about 25 W, less than or about 20 W, or lower. By using a plasma power of less than or about 50 W, the plasma may only remove the portion of the layer of material 330 on the liner 315. As previously discussed, the portion of the layer of material 330 on the liner 315 may be amorphous, whereas the portion of the layer of material 325 on the metal-containing layer 320 may be crystalline. The plasma of the hydrogen-containing precursor, being formed at a plasma power of less than or about 100 W, less than or about 50 W, or less, may only be able to remove the amorphous carbon, otherwise referred to as the portion of the layer of material 330 on the liner 315. The remaining portion of the layer of material 325, the graphenic carbon, may be formed and organized well enough to be substantially unchanged by the plasma of the hydrogen-containing precursor, especially at the low plasma powers according to embodiments of the present technology. That is, poor-quality carbon, such as the carbon on the liner 315 may be removed by plasma formed at a plasma power less than or about 100 W, whereas high-quality carbon, such as the graphene on the metal-containing layer 320, may withstand treatment by the plasma and remain on the structure 300. It is to be understood that although some etching, or removal, of the portion of the layer of material 325 on the metal-containing layer 320 may occur, this removal may be minute, and at a much slower rate than the portion of the layer of material 330 on the liner 315.

At operation 225, the portion of the layer of material 330 on the liner 315 may be removed in less than or about 300 seconds. For example, the portion of the layer of material 330 may be removed in less than or about 250 seconds, less than or about 200 seconds, less than or about 175 seconds, less than or about 150 seconds, less than or about 125 seconds, less than or about 100 seconds, or lower. At removal times of greater than 300 seconds, while the portion of the layer of material 330 on the liner 315 may be entirely removed, longer processing times may lead to etching or removal of the layer of the material on the metal-containing layer 320. Accordingly, etching times may be limited to ensure the graphene is maintained over the metal materials during processing.

Operation 210 and 225 may be formed at the same or similar process conditions. For example, the temperature and/or pressure may be maintained for both the formation of the layer of material and the removal of the portion of the layer of material 330. Conversely, the temperature and/or pressure may be modified or adjusted between the formation of the layer of material and the removal of the portion layer of material 330. For example, in some embodiments the pressure may be reduced during the removal or etching operations. By reducing a pressure within the processing region, a mean-free path of plasma particles may increase, facilitating the removal of the amorphous carbon material. Accordingly, while the deposition may occur at greater than or about 10 Torr, greater than or about 20 Torr, or more, the removal process may occur at less than or about 10 Torr, and may occur at less than or about 8 Torr, less than or about 6 Torr, less than or about 5 Torr, less than or about 4 Torr, less than or about 3 Torr, or less.

The method 200 may include further processing at optional operation 230. For example, operation 230 may include back-end processing, deposition, etching, polishing, cleaning, or any other operations that may be performed subsequent to the described operations. In one embodiment, operation 230 may include depositing low dielectric material on the liner 315, the metal-containing layer 320, and the portion of the layer of material 325 remaining on the metal-containing layer 320. Operation 230 may include etching through the low dielectric material on the liner 315, the metal-containing layer 320, and the portion of the layer of material 325 remaining on the metal-containing layer 320. The etch through the low dielectric material may form a via, which may allow a metal fill operation to connect with one or more of the metal-containing layer 320 plugs.

By utilizing one or more of the described processes, controlled and discrete formation of conductive materials may be provided, leading to improved layers of material and, therefore, structures 300 may be afforded, where one layer, such as the portion of the layer of material 325 including graphene described herein provides properties of both a conductive layer and a barrier layer that is discretely formed on metal materials while maintaining intervening materials free of material that can cause shorting, or with easily removable material, all while utilizing a reduced thickness over conventional technologies. Consequently, improved structures may be afforded by the present technology, which may produce reduced thickness structures with improved overall resistivity over conventional technologies.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a carbon-containing precursor” includes a plurality of such precursors, and reference to “the layer of material” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a carbon-containing precursor to a processing region of a semiconductor processing chamber, wherein a substrate is disposed within the processing region of the semiconductor processing chamber, and wherein the substrate comprises:
a low dielectric constant material defining one or more features,
a liner extending across the low dielectric constant material and within the one or more features, and
a metal-containing layer deposited on the liner and extending within the one or more features;
forming a layer of material on at least a portion of the liner and the metal-containing layer, wherein the layer of material comprises graphene; and
removing substantially all of the portion of the layer of material on the liner.

2. The semiconductor processing method of claim 1, wherein the carbon-containing precursor comprises a carbon-carbon double bond or a carbon-carbon triple bond.

3. The semiconductor processing method of claim 1, wherein a flow rate of the carbon-containing precursor to the processing region of the semiconductor processing chamber is less than or about 1,500 sccm.

4. The semiconductor processing method of claim 1, wherein a temperature within the semiconductor processing chamber is maintained at less than or about 540° C. while forming the layer of material.

5. The semiconductor processing method of claim 1, wherein a pressure within the semiconductor processing chamber is maintained at less than or about 50 Torr while forming the layer of material.

6. The semiconductor processing method of claim 1, wherein:
a temperature within the semiconductor processing chamber is maintained at less than or about 450° C. while forming the layer of material; and
a pressure within the semiconductor processing chamber is maintained at less than or about 25 Torr while forming the layer of material on the substrate.

7. The semiconductor processing method of claim 1, wherein the layer of material is characterized by a carbon concentration of greater than or about 80 at. %.

8. The semiconductor processing method of claim 1, wherein the layer of material formed on the metal-containing layer is characterized by a thickness of less than or about 15 nm.

9. The semiconductor processing method of claim 1, further comprising:
providing a hydrogen-containing precursor to the processing region of the semiconductor region prior to removing substantially all of the portion of the material on the liner.

10. The semiconductor processing method of claim 9, further comprising:
forming a plasma of the hydrogen-containing precursor, wherein the plasma is formed at a plasma power of less than or about 100 W.

11. A semiconductor processing method comprising:
providing a precursor to a processing region of a semiconductor processing chamber, wherein the precursor comprises acetylene, wherein a substrate is disposed within the processing region of the semiconductor processing chamber, and wherein the substrate comprises:
a low dielectric constant material defining one or more features, and
a metal-containing layer deposited on the low dielectric constant material and extending within the one or more features;
forming a layer of material on at least a portion of the low dielectric constant material and the metal-containing layer, wherein the layer of material comprises graphene;
providing a hydrogen-containing precursor to the processing region of the semiconductor region;
forming a plasma of the hydrogen-containing precursor; and
contacting the layer of material with the plasma effluents and removing substantially all of the layer of material on the low dielectric constant material.

12. The semiconductor processing method of claim 11, wherein a flow rate of the carbon-containing precursor to the processing region of the semiconductor processing chamber is less than or about 1,250 sccm.

13. The semiconductor processing method of claim 11, wherein:
a temperature within the semiconductor processing chamber is maintained at less than or about 500° C. while forming the layer of material; and
a pressure within the semiconductor processing chamber is maintained at less than or about 30 Torr while forming the layer of material on the substrate.

14. The semiconductor processing method of claim 11, wherein the layer of material is formed in less than or about 900 seconds.

15. The semiconductor processing method of claim 14, wherein the plasma is formed at a plasma power of less than or about 50 W.

16. A semiconductor processing method comprising:
providing a carbon-containing precursor to a processing region of a semiconductor processing chamber, wherein a substrate is disposed within the processing region of the semiconductor processing chamber;
forming a layer of material on at least a portion of the substrate, wherein the layer of material comprises graphene; and
removing substantially all of the layer of material that is amorphous.

17. The semiconductor processing method of claim 16, wherein:
the substrate comprises a liner defining one or more features and a metal-containing layer deposited on the liner and extending within the one or more features; and
substantially all of the layer of material on the liner is amorphous.

18. The semiconductor processing method of claim 16, wherein the carbon-containing precursor comprises acetylene.

19. The semiconductor processing method of claim 16, wherein the layer of material is formed in less than or about 600 seconds.

20. The semiconductor processing method of claim 16, wherein removing substantially all of the layer of material that is amorphous comprises contacting the layer of material with effluents of a hydrogen-containing plasma.
